(19) United States
(12) Patent Application Publication
(10) Pub. No.: US 2022/0397587 A1
(43) Pub. Date: Dec. 15, 2022

(54) ELASTIC PROBE ELEMENT, ELASTIC PROBE ASSEMBLY, AND TESTING DEVICE

(71) Applicant: teCat Technologies (Suzhou) Limited, Suzhou City (CN)

(72) Inventor: CHOON LEONG LOU, SUZHOU CITY (CN)

(21) Appl. No.: 17/679,312

(22) Filed: Feb. 24, 2022

(30) Foreign Application Priority Data
Jun. 15, 2021 (CN) 202110662218.3

(51) Int. Cl. G01R 1/067; G01R 1/073

(52) U.S. Cl. CPC G01R 1/06716; G01R 1/06772; G01R 1/07357

(57) ABSTRACT

An elastic probe element, an elastic probe assembly, and a testing device are provided. The testing device includes a substrate, a guiding member, and multiple ones of the elastic probe elements. The guiding member has a plurality of through holes for the multiple ones of the elastic probe elements correspondingly passing through. The elastic probe element includes a main body, a first contact segment, and a second contact segment that are integrally formed. The main body has a plurality of needle structures, and any two adjacent needle structures have a gap arranged therebetween. The needle structures are connected to each other through a first connection part and a second connection part arranged at a first end and a second end of the elastic probe element, respectively. The first contact segment is arranged at the first end. The second contact segment is arranged at the second end.

### CROSS-REFERENCE TO RELATED PATENT APPLICATION

This application claims the benefit of priority to China Patent Application No. 202110662218.3, filed on Jun. 15, 2021 in People's Republic of China. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a technical field of high-frequency circuit testing, and more particularly to an elastic probe element, an elastic probe assembly, and a testing device.

### BACKGROUND OF THE DISCLOSURE

A conventional pogo pin includes a plunger, a barrel, and a spring. A size of the conventional pogo pin is difficult to reduce since the spring is arranged in the barrel. In addition, the arrangement of the spring in the conventional pogo pin limits an effective cross-sectional area of current flow, so that a current flow path is easily blocked. As a result, a parasitic inductance value or a parasitic resistance value is accordingly increased, which affects accuracy and reliability of a high-frequency circuit testing.

Therefore, how to improve a structural design so as to overcome the above issues, has become one of the important issues to be addressed in the related field.

### SUMMARY OF THE DISCLOSURE

In response to the above-referenced technical inadequacies, the present disclosure provides an elastic probe element, an elastic probe assembly, and a testing device, which can improve accuracy and reliability of a high-frequency circuit testing.

In one aspect, the present disclosure provides an elastic probe element, which includes a body, a first contact segment, and a second contact segment. The body has a plurality of needle structures. Two adjacent ones of the needle structures have a gap arranged therebetween, and the plurality of needle structures are connected to each other through a first connection part and a second connection part that are respectively arranged at a first end and a second end of the elastic probe element. The first contact segment is arranged at the first end of the elastic probe element. The second contact segment is arranged at the second end of the elastic probe element. The main body, the first contact segment, and the second contact segment are integrally formed.

In another aspect, the present disclosure provides an elastic probe assembly, which includes multiple ones of the elastic probe elements as described above. The multiple ones of the elastic probe elements are stacked in a same direction so as to form the elastic probe assembly. One part of the elastic probe assembly extends along the first end so as to form a first contact end of the elastic probe assembly, and another part of the elastic probe assembly extends along the second end so as to form a second contact end of the elastic probe assembly.

In yet another aspect, the present disclosure provides a testing device, which includes a substrate, at least one guiding member, and multiple ones of the elastic probe elements as described above. The at least one guiding member has a plurality of through holes. The multiple ones of the elastic probe elements are arranged independently from each other and each pass through a corresponding one of the through holes.

In still another aspect, the present disclosure provides a testing device, which includes a substrate, at least one guiding member, and multiple ones of the elastic probe assemblies as described above. The multiple ones of the elastic probe assemblies are arranged independently from each other and each pass through a corresponding one of the through holes. Each of the multiple ones of the elastic probe assemblies includes multiple ones of the elastic probe elements. Each of the multiple ones of the elastic probe elements further has at least one block.

Therefore, one of the beneficial effects of the present disclosure is that, in the elastic probe element, the elastic probe assembly, and the testing device provided by the present disclosure, by virtue of “the body of the probe element having the plurality of needle structures, two adjacent ones of the needle structures having the gap arranged therebetween, the plurality of needle structures being connected to each other through the first connection part and the second connection part that are respectively arranged at the first end and the second end of the elastic probe element, and the elastic probe element being integrally formed” and “the guiding member having the plurality of through holes, the multiple ones of the elastic probe elements being arranged independently from each other and each passing through the corresponding one of the through holes, and each of the plurality of through holes being strip-shaped,” manufacturing the same is easier than the conventional pogo pin, a volume of the body can be effectively reduced, and elasticity of the probe element can be enhanced. In addition, stability of the probe element when abutting against an object to be tested can be strengthened, and a parasitic inductance value or a parasitic resistance value can be further reduced, thereby increasing accuracy and reliability of the high-frequency circuit testing.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic cross-sectional view of an elastic probe element according to a first embodiment of the present disclosure;

FIG. 2 is a schematic cross-sectional view of the elastic probe element which is subjected to a force to buckle according to the first embodiment of the present disclosure;

FIG. 3 is a partial perspective view of a first contact segment of an elastic probe assembly according to the first embodiment of the present disclosure;

FIG. 4 is a partial cross-sectional view of the first contact segment of the elastic probe assembly according to the first embodiment of the present disclosure;

FIG. 5 is a partial perspective view of a second contact segment of the elastic probe assembly according to the first embodiment of the present disclosure;

FIG. 6 is a partial cross-sectional view of the second contact segment of the elastic probe assembly according to the first embodiment of the present disclosure;

FIG. 7 is a schematic exploded view of the elastic probe assembly according to the first embodiment of the present disclosure;

FIG. 8 is a schematic perspective view of the elastic probe assembly according to the first embodiment of the present disclosure;

FIG. 9 is a schematic perspective view of a testing device according to a second embodiment of the present disclosure;

FIG. 10 is a schematic cross-sectional view of the testing device including a block arranged therein according to the second embodiment of the present disclosure;

FIG. 11 is a schematic perspective view of a testing device according to a third embodiment of the present disclosure; and

FIG. 12 is a schematic cross-sectional view of the testing device including a block arranged therein according to the third embodiment of the present embodiment.

Reference numeral: 1. probe element, 10. body, 101. needle structure, 102. gap, 103. first connection part, 104. second connection part, 11. first contact segment, 111. first contact end, 12. second contact segment, 121. second contact end, 13. block, 2. guiding member, 21. through hole, 22. first side, 23. second side, 1′. probe assembly, D. testing device, T1. first end, T2. second end.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

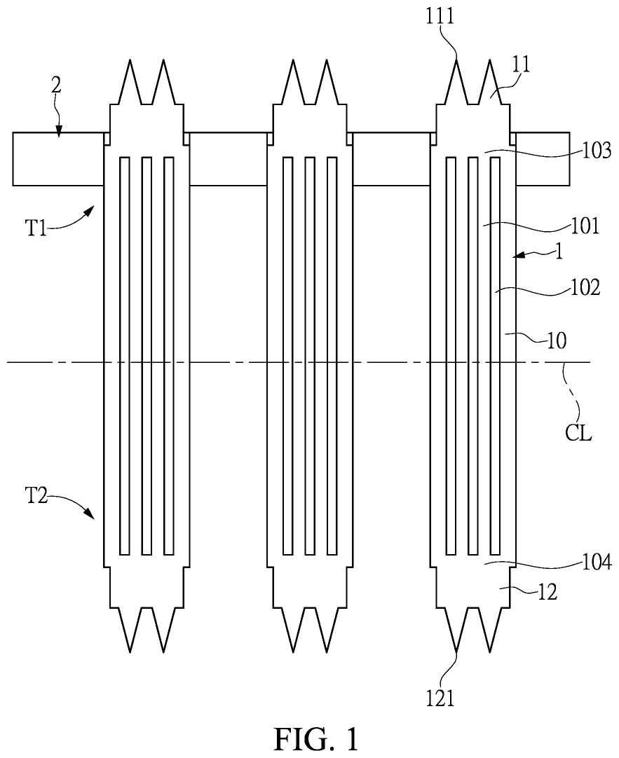

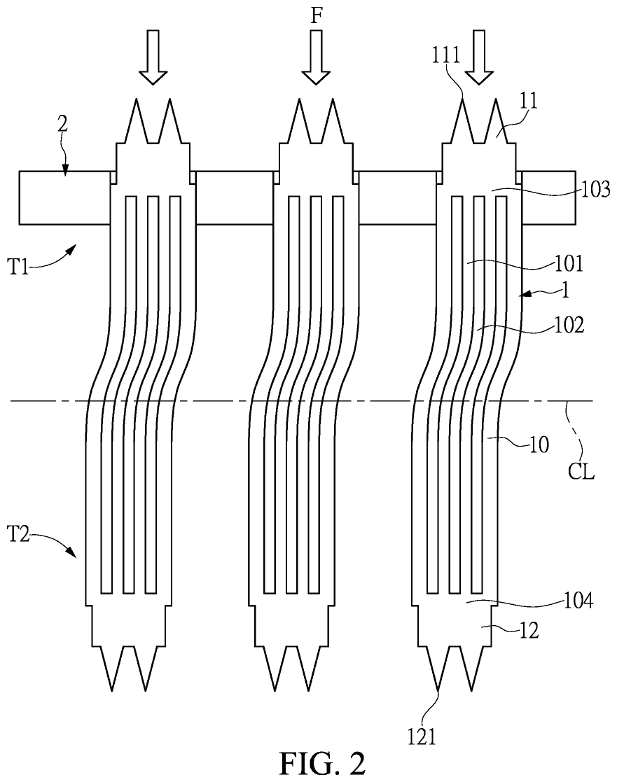

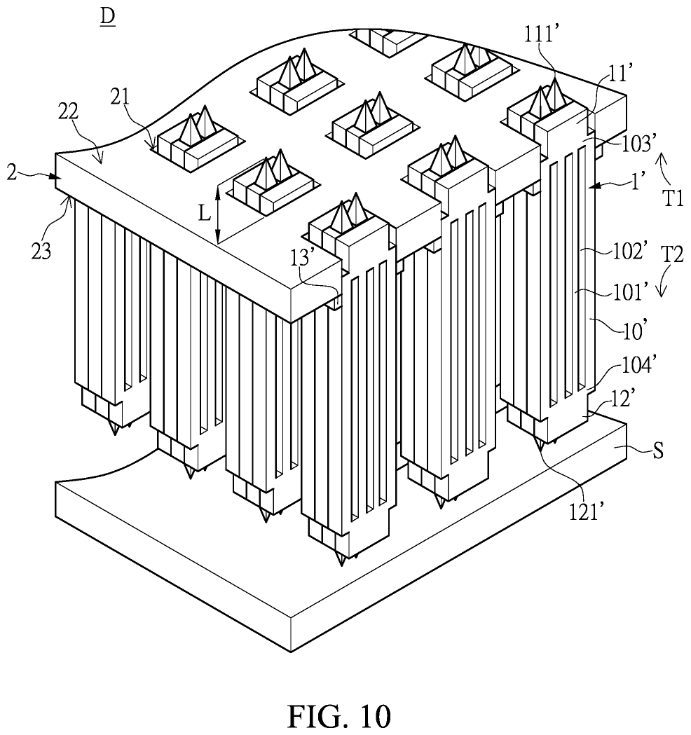

Referring to FIG. 1 and FIG. 2, a first embodiment of the present disclosure provides a probe element 1, which is strip-shaped. The elastic probe element 1 includes a body 10, a first contact segment 11, and a second contact segment 12 (the probe element 1 is passed through by a guiding member 2 as shown FIG. 1 and FIG. 2, and a complete configuration of a testing device of the present disclosure is referred to in FIG. 10 to FIG. 12).

The probe element 1 is integrally formed and can be formed by, for example, a microelectromechanical process, an electroforming process, or a process of laser cutting, but the present disclosure is not limited thereto.

Further, in terms of a center line CL of the probe element 1, the probe element 1 has a first end T1 and a second end T2 that are opposite to each other, and the body 10 has a plurality of needle structures 101 arranged between the first end T1 and the second end T2. The plurality of needle structures 101 are configured for current conduction and signal transmission, and can be made of a highly electrically conductive material. In the present embodiment, a number of the needle structures 101 is at least two, and the at least two needle structures 101 are parallel to and separate from each other. The at least two needle structures 101 have at least one gap 102 arranged therebetween, that is, the at least one gap 102 is arranged between adjacent two of the needle structures 101, but the present disclosure is not limited thereto. In addition, the body 10 has a first connection part 103 toward the first end T1, and a second connection part 104 toward the second end T2. Two ends of each of the plurality of needle structures 101 are respectively connected to the first connection part 103 and the second connection part 104.

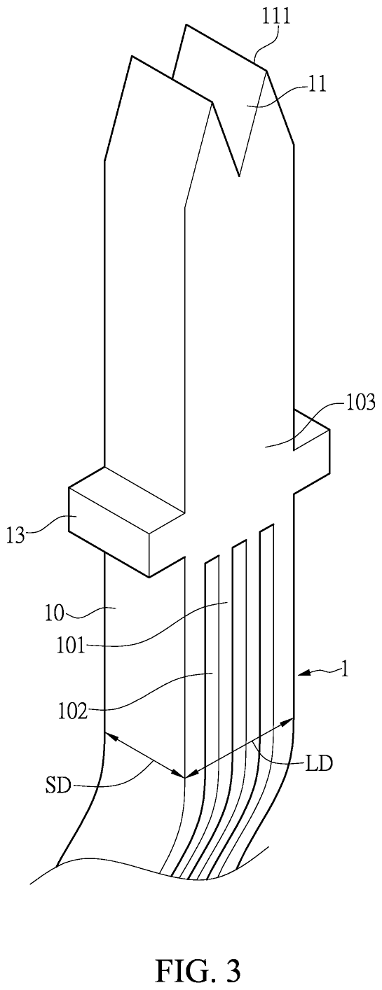

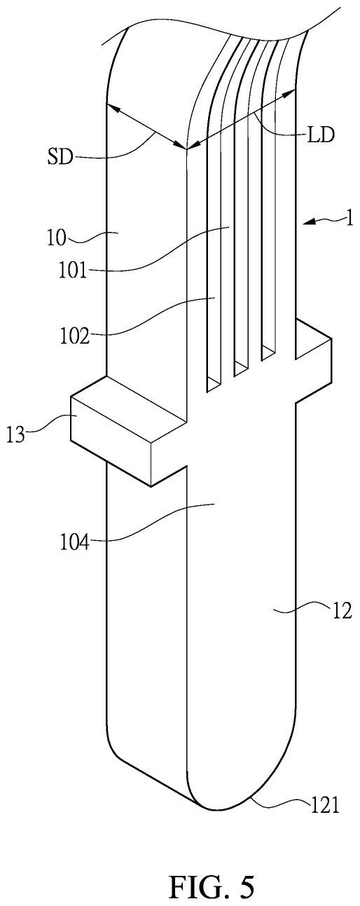

On the other hand, a cross-section of the body 1 is strip-shaped, and the strip-shaped cross-section of the body 1 has a long side LD and a short side SD as shown in FIG. 3 and FIG. 5. Preferably, a length ratio of the long side LD to the short side SD is 3:2, and, when a length of the long side LD is 150 μm, a length of the short side SD is 100 μm. The length of the long side LD and the length side of the short side SD can be adjusted according to elasticity requirements, for example, the length ratio that can be applied for easily deforming the body 1 is 7:1, 7:2, 3:1, 5:2, or 2:1, but the present disclosure is not limited thereto.

Further, referring to FIG. 1 and FIG. 2, in the present embodiment, when the probe element 1 is subjected to a force F in a same direction as an axial direction of the body 10 of the probe element 1, bucking may occur if the force F exceeds a critical load of the probe element 1. To overcome the buckling, the body 10 of the probe element 1 can be made of a material with a high strain property. Therefore, the body 10 of the probe element 1 of the present disclosure can be made of a material with highly electrical conductivity and the high strain property, such as tungsten (W), rhenium-tungsten (ReW), beryllium-copper (BeCu), palladium (HP7), palladium-silver (HC4), tungsten carbide (WC), or alloys thereof, but is not limited thereto.

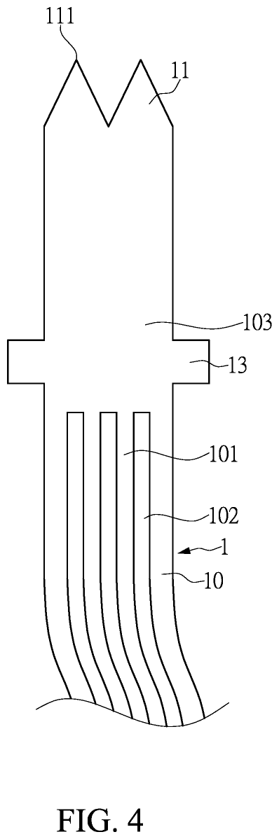

The first contact segment 11 extends along the first end T1, and the second contact segment 12 extends along the second end T2. A first contact end 111 of the first contact segment 11 is used for abutting against an object to be tested (not shown in the figures). In the present embodiment, a shape of the first contact end 111 can be at least one tapered end extending along the first end T1 (as shown in FIG. 1, FIG. 3, and FIG. 4; a block 13 is also shown FIG. 3 and FIG. 4, and detailed descriptions of the block 13 are referred to in a second embodiment and a third embodiment of the present disclosure) or at least one blunt end. For example, a number of each of the tapered ends or the blunt ends can be one, two, three, four, or more. In addition, the blunt end can be rounded, square, or rounded square, but the present disclosure is not limited thereto.

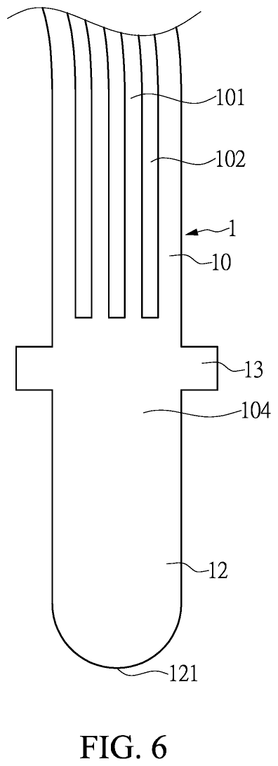

A second contact end 121 of the second contact segment 12 is used for abutting against a substrate S. For example, the substrate S can be a printed circuit board, but the present disclosure is not limited thereto. A shape of the second contact end 121 can be at least one tapered end extending along the second end T2 (as shown in FIG. 1), or at least one blunt end (as shown in FIG. 5 and FIG. 6; the block 13 is also shown FIG. 5 and FIG. 6, and detailed descriptions of the block 13 are referred to in the second embodiment and the third embodiment of the present disclosure). For example, a number of each of the tapered ends or the blunt ends can be one, two, three, four, or more. In addition, the blunt end can be rounded, square, or rounded square, but the present disclosure is not limited thereto.

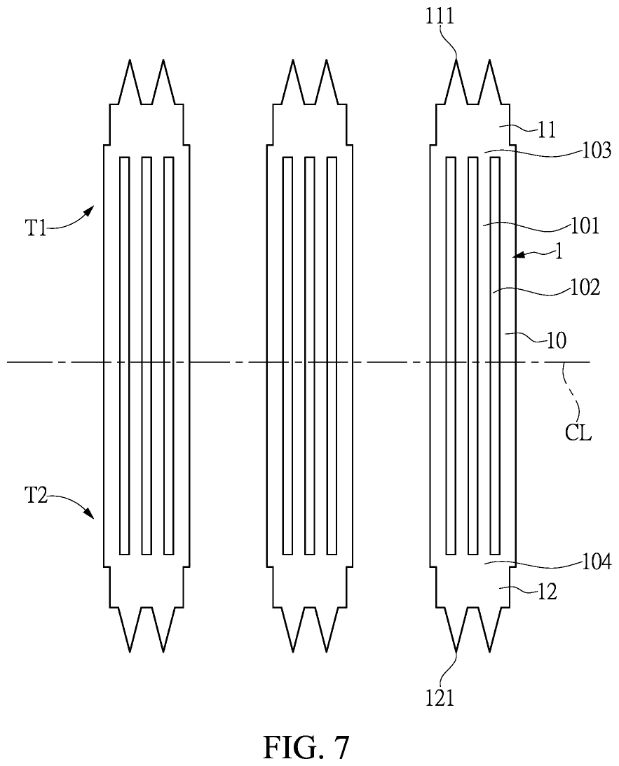

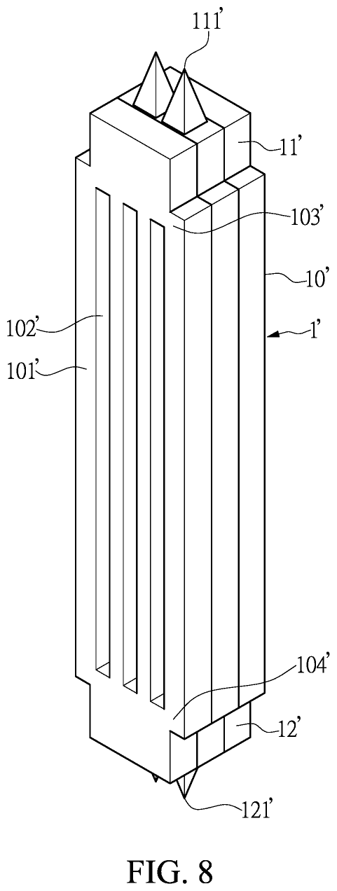

In one embodiment, as shown in FIG. 7 and FIG. 8, FIG. 8 is a schematic view of a probe assembly 1′ formed by a stack of multiple ones of the probe elements 1 according to the present disclosure. In the present embodiment, multiple ones of the probe elements 1 are arranged approximately in parallel to each other and can be stacked in a same direction to form the probe assembly 1′. Specifically, the probe assembly 1′ formed by a stack of three probe elements 1 is exemplarily shown in FIG. 7 and FIG. 8, but the present disclosure is not limited thereto. That is, a number of the probe elements 1 for forming the probe assembly 1′ in a stack manner can be two, three, four, or more. In this way, a flexibility of a body 10′ of the probe assembly 1′ can be increased. In one embodiment, multiple ones of the probe elements 1 are closely attached to each other, so as to increase a strength of the body 10′. In the present embodiment, the probe assembly 1′ has a plurality of needle structures 101′, and the plurality of needle structures 101′ have at least one gap 102′ arranged between each other. That is, two adjacent ones of the plurality of needle structures 101′ have the at least one gap 102′ arranged therebetween, but the present disclosure is not limited thereto. In addition, the body 10′ has a first connection part 103′ toward the first end T1, and a second connection part 104′ toward the second end T2. Two ends of each of the plurality of needle structures 101′ are respectively connected to the first connection part 103′ and the second connection part 104′. In addition, the first contact end 111 of each of the three probe elements 1 has two tapered ends, and the second contact 121 of each of the three probe elements 1 has two tapered ends, so that a first contact segment 11′ extends along the first end T1 and has a first contact end 111′ with the two tapered ends, and a second contact segment 12′ extends along the second end T2 and has a second contact end 121′ with the two tapered ends. In another embodiment, according to practical applications, the first contact ends 111 with different shapes and the second contact ends 121 with different shapes can be stacked to form the first contact end 111′ and the second contact end 121′ with different shapes (e.g., crown-shaped or arc-shaped, but is not limited thereto), so that the first contact end 111′ and the second contact end 121′ of the probe assembly 1′ can be in good and firm contact with the object to be tested and the substrate S, respectively.

However, the aforementioned description is merely an example, and is not meant to limit the scope of the present disclosure.

### Second Embodiment

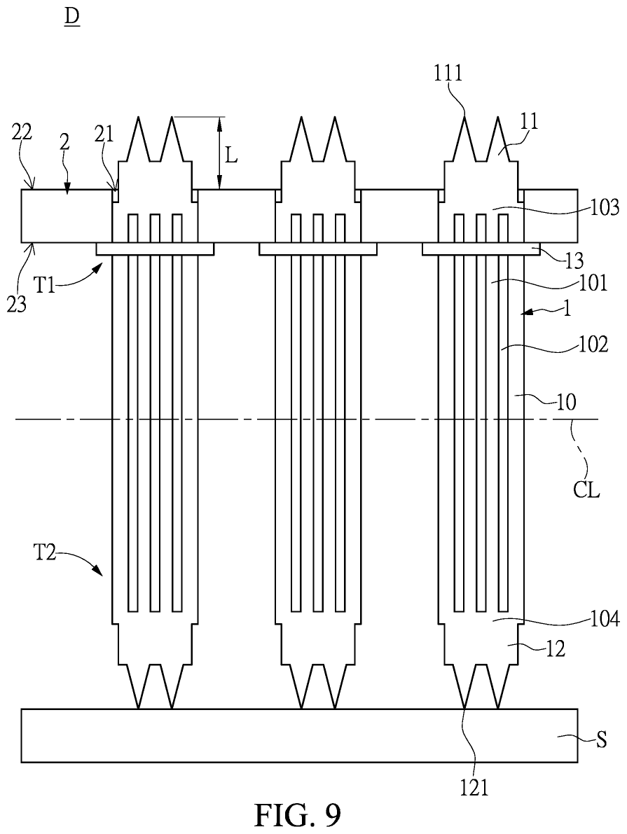

Referring to FIG. 9, a second embodiment of the present disclosure provides a testing device D utilizing an elastic probe, which includes a plurality of probe elements 1, a guiding member 2, and a substrate S.

The plurality of probe elements 1 each are strip-shaped and are independently disposed in the testing device D. The structure and the function of each of the plurality of probe elements 1 are as described in the first embodiment, and will not be reiterated herein.

The guiding member 2 has a plurality of through holes 21 arranged therein, and a shape of each of the plurality of through holes 21 is determined according to a shape of the probe element 1. In the present embodiment, a cross-section of a body 10 of the probe element 1 that is strip-shaped is strip-shaped. Accordingly, the shape of each of the plurality of through holes 21 is strip-shaped so that the probe element 1 can pass through a corresponding one of the plurality of through holes 21, and stability of the probe element 1 can be increased by the through hole 21 that is strip-shaped. The probe element 1 of the present disclosure is integrally formed. In one particular embodiment, the probe element 1 can also have a trapezoidal columnar structure or a polygonal columnar structure, but the present disclosure is not limited thereto. In the present embodiment, the first contact segment 11 of the probe element 1 passes through the through hole 21, so that at least a part of the first contact segment 11 of the probe element 1 is exposed on a first side 22 of the guiding member 2, and the body 10 and the second contact segment 12 of the probe element 1 are arranged on a second side 23 of the guiding member 2. In contrast, a conventional pogo pin has a cylindrical appearance, so that a plurality of circular through holes are needed to be arranged in a guiding member. However, bodies of different probe elements of the conventional pogo pin may move in different directions relative to an axis of a body of the probe element, and such movements of different probe elements cannot be stabilized by the plurality of circular through holes of the guiding member, thereby affecting reliability and accuracy of a test result by the conventional pogo pin.

Further, the plurality of through holes 21 can be arranged in a predetermined pattern on the guiding member 2. The predetermined pattern can be a rectangular array or an annular array, but the present disclosure is not limited thereto. In the present embodiment, one side of each of the plurality of through holes 21 is parallel to a side of the guiding member 2. The plurality of through holes 21 can be arranged in at least one row on the guiding member 2, and the plurality of through holes 21 are spaced apart at one even interval. Moreover, when the plurality of through holes 21 are arranged in multiple rows on the guide 2, the multiple rows are arranged in parallel with each other at another even interval, so that the plurality of through holes 21 are arranged in the rectangular array.

Further, in the present embodiment, the probe element 1 also includes a block 13. The block 13 is formed by a part of the first contact segment 11 protruding from the first contact segment 11, that is, the block 13 is formed on an outer surface of the first contact segment 11. In addition, the block 13 is arranged on a side of the first contact segment 11 that is away from the first contact end 111, so as to define a distance L of the first contact end 111 of the first contact segment 11 that is exposed from the guiding member 2. In one embodiment, a part of the first contact segment 11 is accommodated in the through hole 21. In one embodiment, the first connection part 103 is accommodated in the through hole 21. Through such an arrangement of the present disclosure, the first connection part 103 can have a better stress to withstand the force F during a process of testing, so as to effectively avoid a fracture of the first connection part 103. According to use environments, the block 13 can be arranged on the first side 22 or the second side 23. The present disclosure is not limited by a shape of the block 13, as long as the block 13 can abut against a part of the guiding member 2 that is around the through hole 21, so that the probe element 1 can be fixedly arranged in a predetermined position. More specifically, a structure of the block 13 can be adjusted according to a user's demand or practical applications, and a shape of a cross-section of the block 13 can be, for example, but not limited to, hollow square, hollow circle, hollow triangle, or arc-shaped. In addition, the body 10, the first contact segment 11, the second contact segment 12, and the block 13 are integrally formed. Similarly, the present disclosure is not limited to a molding method. For example, the body 10, the first contact segment 11, the second contact segment 12, and the block 13 can be formed by the microelectromechanical process, the electroforming process, or the process of laser cutting.

In the present embodiment, as shown in FIG. 10, multiple ones of the probe elements 1 are stacked to form the probe assembly 1′ which passes through the through hole 21, and a size of the through hole 21 is determined according to an area of a cross-section of the body 10′ of the probe assembly 1′. In the present embodiment, multiple ones of the probe elements 1 are arranged approximately in parallel to each other and can be stacked in the same direction to form the probe assembly 1′. The number of the probe elements 1 for forming the probe assembly 1′ in the stack manner can be two, three, four, or more. In this way, the flexibility of the body 10′ of the probe assembly 1′ can be increased. In one embodiment, multiple ones of the probe elements 1 are closely attached to each other, so as to increase the strength of the body 10′. For example, as described in the first embodiment, the probe assembly 1′ has the plurality of needle structures 101′, and the plurality of needle structures 101′ have the at least one gap 102′ arranged between each other. That is, two adjacent ones of the plurality of needle structures 101′ have the at least one gap 102′ arranged therebetween, but the present disclosure is not limited thereto. In addition, the body 10′ has the first connection part 103′ toward the first end T1, and the second connection part 104′ toward the second end T2. Two ends of each of the plurality of needle structures 101′ are respectively connected to the first connection part 103′ and the second connection part 104′. In addition, the first contact end 111 of each of the three probe elements 1 has two tapered ends, and the second contact 121 of each of the three probe elements 1 has two tapered ends, so that the first contact segment 11′ extends along the first end T1 and has the first contact end 111′ with the two tapered ends, and the second contact segment 12′ extends along the second end T2 and has the second contact end 121′ with the two tapered ends. In this way, the first contact end 111′ and the second contact end 121′ of the probe assembly 1′ can be in good and firm contact with the object to be tested and the substrate S, respectively. The present disclosure is not limited by the examples described above.

According to the above, the probe assembly 1′ can also include a block 13′. The block 13′ is formed by a part of the first contact segment 11′ protruding from the first contact segment 11′, that is, the block 13′ is formed on an outer surface of the first contact segment 11′. In addition, the block 13′ is arranged on a side of the first contact segment 11′ that is away from the first contact end 111′, so as to define a distance L of the first contact end 111′ of the first contact segment 11′ that is exposed from the guiding member 2. In one embodiment, a part of the first contact segment 11′ is accommodated in the through hole 21. In one embodiment, the first connection part 103′ is accommodated in the through hole 21. Through such an arrangement of the present disclosure, the first connection part 103′ can have a better stress to withstand the force F during a process of testing, so as to effectively avoid a fracture of the first connection part 103′. The present disclosure is not limited by a shape of the block 13′, as long as the block 13′ can abut against a part of the guiding member 2 that is around the through hole 21, so that the probe element 1′ can be fixedly arranged in a predetermined position. More specifically, a structure of the block 13′ can be adjusted according to the user's demand or the practical applications, and a shape of a cross-section of the block 13′ can be, for example, but not limited to, hollow square, hollow circle, hollow triangle, or arc-shaped. In addition, the body 10′, the first contact segment 11′, the second contact segment 12′, and the block 13′ are integrally formed by an electrical conductor. Similarly, the present disclosure is not limited to a molding method. For example, the body 10′, the first contact segment 11′, the second contact segment 12′, and the block 13′ can be formed by the microelectromechanical process, the electroforming process, or the process of laser cutting.

In the present embodiment, the substrate S can be the printed circuit board, but the present disclosure is not limited thereto.

However, the aforementioned description is merely an example, and is not meant to limit the scope of the present disclosure.

### Third Embodiment

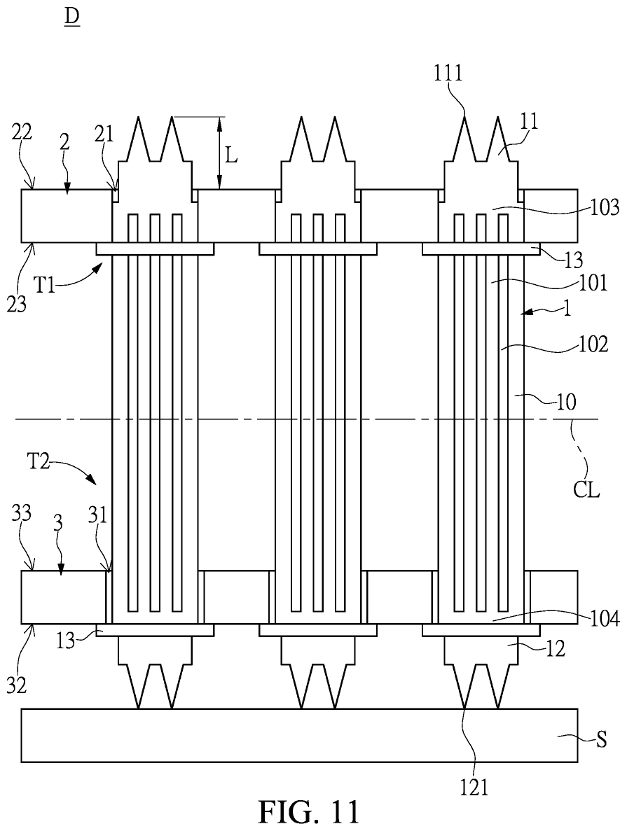

Referring to FIG. 11, a third embodiment of the present disclosure provides a testing device D utilizing an elastic probe, which includes a plurality of probe elements 1, at least one upper guiding member 2 (i.e., the guiding member 2 of the second embodiment), at least one lower guiding member 3, and a substrate S. In addition, the main difference between the testing device D of the third embodiment and the testing device D of the second embodiment is that, the testing device D of the present embodiment includes two guiding members.

The plurality of probe elements 1 each are strip-shaped and are independently disposed in the testing device D. The structure and the function of each of the plurality of probe elements 1 are as described in the first embodiment, and will not be reiterated herein.

The at least one upper guiding member 2 (i.e., the guiding member 2 of the second embodiment) has a plurality of first through holes 21 (i.e., the through holes 21 of the second embodiment) arranged therein, the at least one lower guiding member 3 has a plurality of second through holes 31 arranged therein, and the plurality of first through holes 21 respectively correspond to the plurality of second through holes 31. A shape of each of the plurality of first through holes 21 and a shape of each of the plurality of second through holes 31 are determined according to a shape of the probe elements 1. In the present embodiment, the first contact segment 11 of the probe element 1 passes through the through hole 21, so that at least a part of the first contact segment 11 of the probe element 1 is exposed from a first side 22 of the upper guiding member 2, and the second contact segment 12 of the probe element 1 passes through the second through hole 31, so that at least a part of second contact segment 12 of the probe element 1 is exposed from a first side 32 of the lower guiding member 3. In addition, the body 10 of the probe element 1 is arranged between a second side 23 of the upper guiding member 2 and a second side 33 of the lower guiding member 3.

Further, in the present embodiment, the probe element 1 also includes at least one block 13. The block 13 is formed by a part of the first contact segment 11 and/or a part of the second contact segment 12 respectively protruding from the first contact segment 11 and the second contact segment 12, that is, the block 13 is formed on an outer surface of the first contact segment 11 and/or an outer surface of the second contact segment 12. In addition, the block 13 is arranged on a side of the first contact segment 11 and/or a side of the second contact segment 12 that are away from the first contact end 111, so as to define a distance L of the first contact end 111 of the first contact segment 11 that is exposed from the guiding member 2. In one embodiment, a part of the first contact segment 11 is accommodated in the first through hole 21. In one embodiment, the first connection part 103 is accommodated in the first through hole 21. Through such an arrangement of the present disclosure, the first connection part 103 can have a better stress to withstand the force F during a process of testing, so as to effectively avoid a fracture of the first connection part 103. According to use environments, the block 13 can be arranged on the first side 22 of the upper guiding member 2, the second side 23 of the upper guiding member 2, the first side 32 of the lower guiding member 3, or the second side 33 of the lower guiding member 3. For example, when one block 13 is arranged on the first side 22 of the upper guiding member 2, another block 13 is arranged on the first side 32 of the lower guiding member 3; when one block 13 is arranged on the second side 23 of the upper guiding member 2, another block 13 is arranged on the second side 33 of the lower guiding member 3, but the present disclosure is not limited thereto. The present disclosure is not limited by a shape of the block 13, as long as the block 13 can abut against a part of the upper guiding member 2 and/or a part of the lower guiding member 3 that are respectively around the first through hole 21 and the second through hole 31, so that the probe element 1 can be fixedly arranged in a predetermined position. More specifically, a structure of the block 13 can be adjusted according to a user's demand or practical applications, and a shape of a cross-section of the block 13 can be, for example, but not limited to, hollow square, hollow circle, hollow triangle, or arc-shaped. In addition, the body 10, the first contact segment 11, the second contact segment 12, and the block 13 are integrally formed by an electrical conductor. Similarly, the present disclosure is not limited to a molding method. For example, the body 10, the first contact segment 11, the second contact segment 12, and the block 13 can be formed by a microelectromechanical process, an electroforming process, or a process of laser cutting.

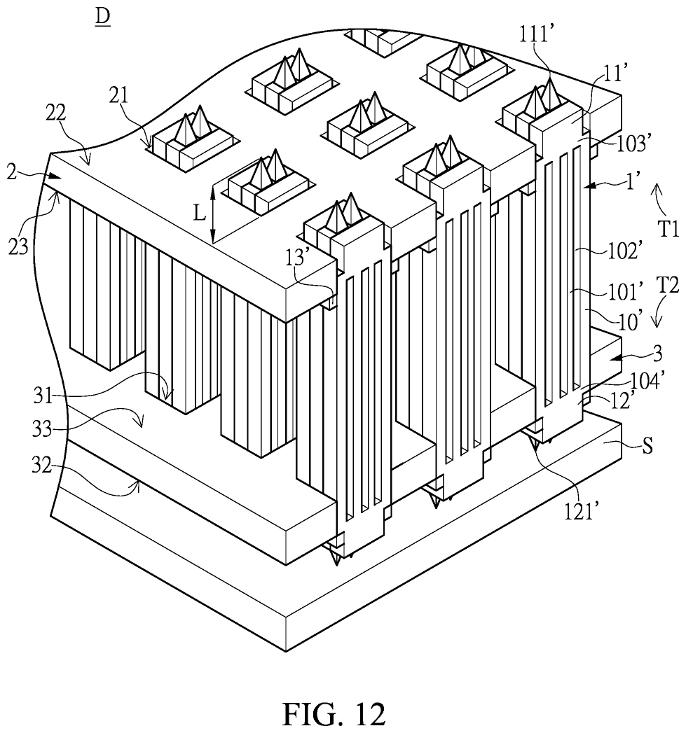

In one embodiment, as shown in FIG. 12, multiple ones of the probe elements 1 are stacked to form the probe assembly 1′ which correspondingly passes through the first through hole 21 and the second through hole 31, and each of a size of the first through hole 21 and size of the second through hole 31 is determined according to an area of a cross-section of the body 10′ of the probe assembly 1′. In the present embodiment, multiple ones of the probe elements 1 are arranged approximately in parallel to each other and can be stacked in the same direction to form the probe assembly 1′. A number of the probe elements 1 for forming the probe assembly 1′ in the stack manner can be two, three, four, or more. In this way, a flexibility of the body 10′ of the probe assembly 1′ can be increased. For example, as described in the first embodiment, the first contact end 111 of each of the three probe elements 1 has two tapered ends, and the second contact 121 of each of the three probe elements 1 has two tapered ends, so that the first contact segment 11′ extends along the first end T1 and has the first contact end 111′ with the two tapered ends, and the second contact segment 12′ extends along the second end T2 and has the second contact end 121′ with the two tapered ends. In this way, the first contact end 111′ and the second contact end 121′ of the probe assembly 1′ can be in good and firm contact with the object to be tested and the substrate S, respectively. The present disclosure is not limited by the examples described above.

According to the above, the probe assembly 1′ can also include a block 13′. The block 13′ is formed by a part of the first contact segment 11′ and/or a part of the second contact segment 12′ protruding respectively from the first contact segment 11′ and the second contact segment 12′, that is, the block 13′ is formed on an outer surface of the first contact segment 11′ and/or an outer surface of the second contact segment 12′. In addition, the block 13′ is arranged on a side of the first contact segment 11′ and/or a side of the second contact segment 12′ that are away from the first contact end 111′, and are adjacent to the first through hole 21 and the second through hole 31, respectively. The present disclosure is not limited by a shape of the block 13′, as long as the block 13′ can abut against a part of the upper guiding member 2 (i.e., the guiding member 2 of the second embodiment) or a part of the lower guiding member 3 that are respectively around the first through hole 21 and the second through hole 31, so that the probe element 1′ can be fixedly arranged in a predetermined position. More specifically, a structure of the block 13′ can be adjusted according to the user's demand or the practical applications, and a shape of a cross-section of the block 13′ can be, for example, but not limited to, hollow square, hollow circle, hollow triangle, or arc-shaped. In addition, the body 10′, the first contact segment 11′, the second contact segment 12′, and the block 13′ are integrally formed by an electrical conductor. Similarly, the present disclosure is not limited to a molding method. For example, the body 10′, the first contact segment 11′, the second contact segment 12′, and the block 13′ can be formed by the microelectromechanical process, the electroforming process, or the process of laser cutting.

In the present embodiment, the substrate S can be the printed circuit board, but the present disclosure is not limited thereto.

However, the aforementioned description is merely an example, and is not meant to limit the scope of the present disclosure.

[Beneficial Effects of the Embodiments]

In conclusion, one of the beneficial effects of the present disclosure is that, in the elastic probe element 1, the elastic probe assembly 1′, and the testing device D provided by the present disclosure, by virtue of “the body 10 of the probe element 1 having the plurality of needle structures 101, two adjacent ones of the needle structures 101 having the gap 102 arranged therebetween, and the plurality of needle structures 101 being connected to each other through the first connection part 103 and the second connection part 104 that are respectively arranged at the first end T1 and the second end T2 of the elastic probe element 1” and “the guiding member 2 having the plurality of through holes 21, the multiple ones of the elastic probe elements 1 being arranged independently from each other and each passing through the corresponding one of the through holes 21, and each of the plurality of through holes 21 being strip-shaped,” manufacturing the same is easier than the conventional pogo pin, a volume of the body can be effectively reduced, and elasticity of the probe element can be enhanced. In addition, stability of the probe element when abutting against the object to be tested can be strengthened, and the parasitic inductance value or the parasitic resistance value can be further reduced, thereby increasing accuracy and reliability of a high-frequency circuit testing.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An elastic probe element, comprising:
a body having a plurality of needle structures, wherein two adjacent ones of the needle structures have a gap arranged therebetween, and the plurality of needle structures are connected to each other through a first connection part and a second connection part that are respectively arranged at a first end and a second end of the elastic probe element;
a first contact segment arranged at the first end of the elastic probe element; and
a second contact segment arranged at the second end of the elastic probe element;
wherein the main body, the first contact segment, and the second contact segment are integrally formed.

2. The elastic probe element according to claim 1, wherein the body is made of a highly electrically conductive material.

3. The elastic probe element according to claim 1, wherein the first end includes at least one first tapered end, and the second end includes at least one second tapered end.

4. The elastic probe element according to claim 1, wherein the plurality of needle structures of the body are parallel to each other.

5. An elastic probe assembly, comprising:
multiple ones of the elastic probe elements according to claim 1;
wherein the multiple ones of the elastic probe elements are stacked in a same direction so as to form the elastic probe assembly;
wherein one part of the elastic probe assembly extends along the first end so as to form a first contact end of the elastic probe assembly, and another part of the elastic probe assembly extends along the second end so as to form a second contact end of the elastic probe assembly.

6. A testing device, comprising:
a substrate;
at least one guiding member having a plurality of through holes; and
multiple ones of the elastic probe elements according to claim 1 respectively corresponding to the plurality of through holes, and each passing through a corresponding one of the through holes.

7. The testing device according to claim 6, wherein each of the plurality of through holes is strip-shaped.

8. The testing device according to claim 6, wherein the plurality of through holes are arranged in a predetermined pattern on the at least one guiding member.

9. The testing device according to claim 6, further comprising:
at least one block arranged on a side of the first contact segment that is away from a first contact end and is adjacent to a corresponding one of the through holes.

10. The testing device according to claim 6, wherein a part of the first contact segment is accommodated in a corresponding one of the through holes.

11. The testing device according to claim 6, wherein the first connection part is accommodated in a corresponding one of the through holes.

12. A testing device, comprising:
a substrate;
at least one guiding member having a plurality of through holes; and
multiple ones of the elastic probe assemblies according to claim 5 respectively corresponding to the plurality of through holes, and each passing through a corresponding one of the through holes.

13. The testing device according to claim 12, wherein each of the plurality of through holes is strip-shaped.

14. The testing device according to claim 12, further comprising:
at least one block arranged on a side of the first contact segment or a side of the second contact segment that is away from the first contact end and is adjacent to a corresponding one of the through holes.
